(19) United States
(12) Patent Application Publication
(10) Pub. No.: US 2023/0039660 A1
(43) Pub. Date: Feb. 9, 2023

(54) SiC EPITAXIAL WAFER AND METHOD FOR MANUFACTURING SiC EPITAXIAL WAFER

(71) Applicant: SHOWA DENKO K.K., Tokyo (JP)

(72) Inventors: Kensho TANAKA, Chichibu-shi (JP); Yoshikazu Umeta, Chichibu-shi (JP)

(73) Assignee: SHOWA DENKO K.K., Tokyo (JP)

(21) Appl. No.: 17/879,118

(22) Filed: Aug. 2, 2022

(30) Foreign Application Priority Data
Aug. 4, 2021 (JP) 2021-128278

(51) Int. Cl. H01L 29/16; H01L 21/02

(52) U.S. Cl. CPC H01L 29/1608; H01L 21/0262; H01L 21/02381

(57) ABSTRACT

A SiC epitaxial wafer includes a SiC substrate and an epitaxial layer laminated on the SiC substrate, wherein the epitaxial layer contains an impurity element which determines the conductivity type of the epitaxial layer and boron which has a conductivity type different from the conductivity type of the impurity element, and the concentration of boron in the center of the epitaxial layer is less than 5.0×10¹² cm⁻³.

### BACKGROUND OF THE INVENTION

### Field of the Invention

The present disclosure relates to a SiC epitaxial wafer and a method of manufacturing a SiC epitaxial wafer.

Priority is claimed on Japanese Patent Application No. 2021-128278, filed on Aug. 4, 2021, the content of which is incorporated herein by reference.

### Description of Related Art

Silicon carbide (SiC) has an insulation breakdown electric field that is an order of magnitude larger than silicon (Si), a band gap that is three times larger than silicon (Si), and a thermal conductivity that is about three times higher than silicon (Si). Silicon carbide (SiC) is expected to be applied to power devices, high frequency devices, high temperature operation devices and the like.

In order to promote practical use of SiC devices, it is required to establish high-quality SiC epitaxial wafers and high-quality epitaxial growth techniques.

The SiC device is formed on a SiC epitaxial wafer. The SiC epitaxial wafer includes an SiC substrate and an epitaxial layer laminated on the SiC substrate. The SiC substrate is obtained by processing a bulk single crystal of SiC grown by a sublimation recrystallization method or the like. The epitaxial layer is formed by chemical vapor deposition (CVD) or the like, and serves as an active region of the device.

The epitaxial layer may have an impurity element which determines the conductivity type of the epitaxial layer and boron which has a conductivity type different from the conductivity type of the impurity element (for example, Patent Literatures 1˜3). Boron may reduce the effective carrier concentration in the drift layer and may result in a shorter carrier lifetime of the bipolar device.

Although it is difficult to completely remove boron because it is contained in a member or the like used for manufacturing, further reduction of the concentration of boron is required.

### CITATION LIST

### Patent Literature

[Patent Literature 1]

Japanese Unexamined Patent Application, First Publication No. 2019-121690
[Patent Literature 2]

PCT International Publication No. 2006/008941
[Patent Literature 3]

PCT International Publication No. 2018/193664

### SUMMARY OF THE INVENTION

A first aspect of the present disclosure provides a SiC epitaxial wafer including a SiC substrate and an epitaxial layer of SiC laminated on the SiC substrate, wherein the epitaxial layer contains an impurity element which determines the conductivity type of the epitaxial layer and boron which has a conductivity type different from the conductivity type of the impurity element, and the concentration of boron in the center of the epitaxial layer is less than 5.0×10¹² cm⁻³.

In the SiC epitaxial wafer according to the first aspect, the diameter may be 150 mm or more.

In the SiC epitaxial wafer according to the first aspect, the diameter may be 200 mm or more.

A second aspect of the present disclosure provides a method of manufacturing a SiC epitaxial wafer including a film-forming step of forming an epitaxial layer of SiC on a SiC substrate using a vertical furnace having a gas supply port above a mounting surface of the SiC substrate, wherein the film-forming step comprises a temperature raising step of raising the temperature to a film-forming temperature while changing the temperature raising speed in the order of a first temperature raising speed, a second temperature raising speed, and a third temperature raising speed, wherein the first temperature raising speed is faster than the second temperature raising speed, the second temperature raising speed is faster than the third temperature raising speed, and the first temperature raising speed is 100° C./min or more, and wherein in the film forming step, the temperature of the gas supply port and an upstream member in the middle of the gas flow path from the gas supply port to the mounting surface is set to 1200° C. or less.

In the method of manufacturing a SiC epitaxial wafer according to the second aspect, the gas supply port and the upstream member may be carbon members in which a plurality of SiC layers are laminated.

In the method of manufacturing a SiC epitaxial wafer according to the second aspect, in the mounting surface of the SiC substrate, the height position of the center may be 30 μm or more higher than the height position of the outer periphery at the film-forming temperature.

In the method of manufacturing a SiC epitaxial wafer according to the second aspect, the time required for the temperature raising step may be 300 seconds or more and 750 seconds or less.

In the method of manufacturing a SiC epitaxial wafer wafer according to the second aspect, the SiC substrate may be transferred to the vertical furnace at a temperature of 500° C. or higher.

In the method of manufacturing a SiC epitaxial wafer according to the second aspect, in the film-forming step, a purge gas may be supplied from the back surface of the SiC substrate, and the purge gas may be supplied from a position 20 mm or more inside the outer periphery of the SiC substrate.

### BRIEF DESCRIPTION OF THE DRAWINGS

FIG. 1 is a cross-sectional view of a SiC epitaxial wafer according to the first embodiment.

FIG. 2 is a plan view of the SiC epitaxial wafer according to the first embodiment.

FIG. 3 is a schematic view of an example of a film-forming apparatus for the SiC epitaxial wafer according to the first embodiment.

FIG. 4 is an example of the film-forming process of the SiC epitaxial wafer according to the first embodiment.

FIG. 5 is an enlarged view of the vicinity of the SiC substrate of the film-forming apparatus for the SiC epitaxial wafer according to the first embodiment.

FIG. 6 is a schematic view of another example of a film-forming apparatus for the SiC epitaxial wafer according to the first embodiment.

### DETAILED DESCRIPTION OF THE INVENTION

Hereinafter, this embodiment will be described in detail with reference to the drawings. The drawings used in the following description may show, for convenience's sake, the features of the present disclosure in enlarged form, and the dimensional proportions of the components may be different from those in practice. The materials, dimensions, and the like exemplified in the following description are only examples, and the present disclosure is not limited thereto, and the disclosure can be carried out by appropriately changing the gist thereof without changing it.

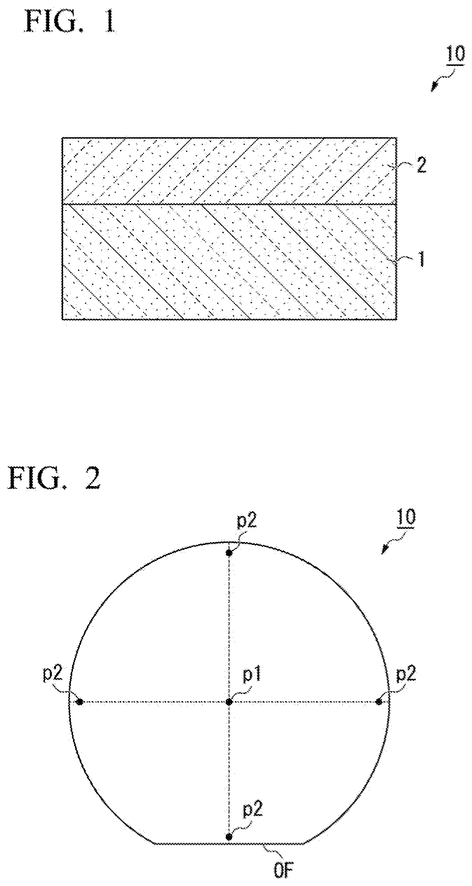

FIG. 1 is a cross-sectional view of a SiC epitaxial wafer 10 according to the first embodiment. FIG. 2 is a plan view of the SiC epitaxial wafer 10 according to the first embodiment. The SiC epitaxial wafer 10 has a SiC substrate 1 and an epitaxial layer 2 thereon. The SiC epitaxial wafer 10 is, for example, a disk having a diameter of 150 mm or more. The diameter of the SiC epitaxial wafer 10 may be 200 mm or more.

The SiC substrate 1 is cut out from, for example, a SiC ingot. The SiC ingot is grown on a SiC seed crystal using, for example, a sublimation method. In the SiC substrate 1, for example, a surface having an offset angle in the <11-20> direction from (0001) is used as a growth surface. The SiC substrate 1 contains impurities. The impurity is, for example, nitrogen.

The SiC substrate 1 has, for example, a circular shape in plan view. The diameter of the SiC substrate 1 is, for example, 150 mm or more. A portion of the circle of the SiC substrate 1 may be cut off. The notched portion is referred to as the orientation flat OF. The orientation flat OF is used to confirm the orientation or the like of the SiC substrate 1.

The epitaxial layer 2 is laminated on the SiC substrate 1. The epitaxial layer 2 is formed by, for example, chemical vapor deposition (CVD). The epitaxial layer 2 is a single crystal film of SiC. The epitaxial layer 2 may be composed of, for example, a plurality of layers. For example, the epitaxial layer 2 may be composed of a plurality of SiC single crystal films having different impurity concentrations.

The epitaxial layer 2 includes an impurity element for determining a conductivity type of the epitaxial layer 2 and boron. The impurity element for determining the conductivity type is, for example, nitrogen. The conductivity type of nitrogen is n-type. The concentration of the impurity determining the conductivity type of the epitaxial layer 2 is, for example, 1.0×10¹⁴ cm⁻³ or more and 3.0×10¹⁶ cm⁻³ or less, preferably 1.0×10¹⁴ cm⁻³ or more and 3.0×10¹⁵ cm⁻³ or less. The in-plane uniformity of the impurity concentration determining the conductivity type in the epitaxial layer 2 is preferably, for example, 20% or less, and more preferably 10% or less. The in-plane uniformity of the impurity concentration determining the conductivity type is obtained, for example, from the results of 10 or more measurement points in the radial direction passing through the center of the SiC epitaxial wafer. The in-plane uniformity of the impurity concentration is a value obtained by dividing the difference between the maximum value and the minimum value of the impurity concentration among the plurality of measurement points by the average value of the impurity concentration among the plurality of measurement points. The measurement points may be arranged in a direction parallel to the orientation flat OF, in a direction perpendicular to the orientation flat OF, or in directions parallel to and perpendicular to the orientation flat OF.

Boron shows a conductivity type different from that of nitrogen. The conductive type of boron is p-type. Boron is not intentionally doped in the epitaxial layer 2, but when the epitaxial layer 2 is formed, boron contained in a susceptor or the like in the film-forming apparatus is mixed as an impurity. Boron can cause a decrease in an effective carrier concentration and can also suppress the conductivity modulation effect of the bipolar device. The concentration of boron in the epitaxial layer 2 is preferably small, but it is difficult to completely remove boron.

The concentration of boron at the center pl of the epitaxial layer 2 is 5.0×10¹² cm⁻³ or less. The concentration of boron at the point p2 on the outer peripheral side of the epitaxial layer 2 is preferably less than 1.0×10¹⁴ cm⁻³. The point p2 is a position 5 mm inside the outer periphery of the epitaxial layer 2. An area of 5 mm from the outer periphery may often not be regarded as an effective area of the device. Therefore, the area of 5 mm from the outer periphery is often negligible.

The concentration of impurities and boron in each layer can be measured by, for example, a mercury probe (Hg-CV) method or secondary ion mass spectrometry (SIMS).

In the Hg-CV method, the difference (Nd-Na) between the donor concentration Nd and the acceptor concentration Na is measured as an n-type impurity concentration. If the acceptor concentration is sufficiently small compared to the donor concentration, the difference between these concentrations can be regarded as the n-type impurity concentration.

Secondary ion mass spectrometry (SIMS) is a method of performing mass spectrometry on secondary ions that have popped out while dogging a layer in the thickness direction. The doping concentration can be measured from mass spectrometry.

Next, a method of manufacturing a SiC epitaxial wafer according to the first embodiment will be described. First, an SiC substrate 1 is prepared. The SiC substrate 1 is obtained by cutting the SiC ingot with a predetermined thickness. The SiC substrate 1 may be purchased for sale.

Next, a film-forming step of forming an epitaxial layer 2 on the SiC substrate 1 is performed. The epitaxial layer 2 is formed by, for example, CVD.

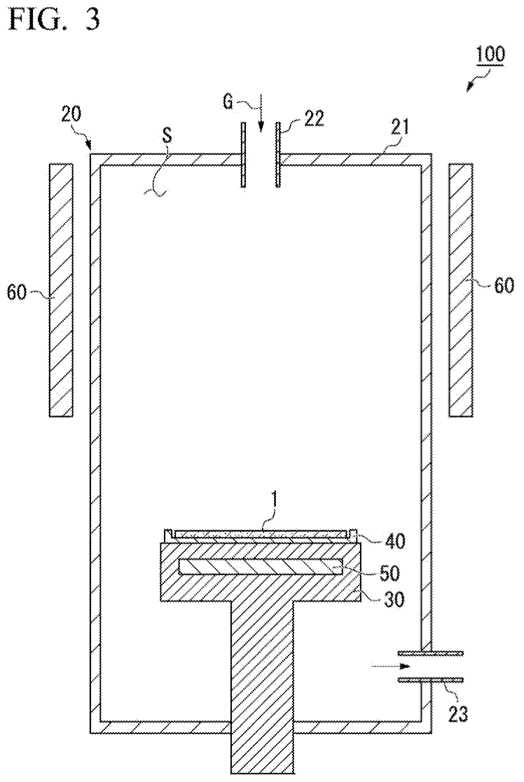

FIG. 3 is a schematic view of an example of a film-forming apparatus 100 for a SiC epitaxial wafer 10 according to the first embodiment. The film-forming apparatus 100 includes, for example, a chamber 20, a support 30, a susceptor 40, a lower heater 50, and an upper heater 60. FIG. 3 shows a state in which the SiC substrate 1 is mounted on the susceptor 40. The film-forming apparatus 100 is a vertical furnace having a gas supply port 22 above the mounting surface of the SiC substrate 1.

The chamber 20 has, for example, a body 21, a gas supply port 22, and a gas discharge port 23. The main body 21 surrounds the film-forming space S. The gas supply port 22 is an inlet for supplying the film-forming gas G to the film-forming space S. The gas supply port 22 is located, for example, above the mounting surface of the SiC substrate 1. The gas discharge port 23 is an outlet for discharging the film-forming gas G and the like retained in the film-forming space S. The gas discharge port 23 is located, for example, below the mounting surface of the SiC substrate 1. The film-forming gas G is, for example, a Si-based gas, a C-based gas, a purge gas, and a dopant gas.

The Si-based gas is a source gas containing Si in the molecule. The Si-based gas is, for example, silane (SiH₄), dichlorosilane (SiH₂Cl₂), trichlorosilane (SiHCl₃), tetrachlorosilane (SiCl₄) or the like. The C-based gas is, for example, propane (C₃H₈), ethylene (C₂H₄) or the like. The dopant gas is a gas containing an element serving as a carrier. The dopant gas is, for example, nitrogen, ammonia or the like. The purge gas is a gas for conveying these gases to the SiC substrate 1, and is hydrogen or the like that is inert to SiC.

The gas supply port 22 includes, for example, a carbon member and a SiC or TaC layer for coating its surface. Since the surface of the gas supply port 22 is coated with SiC or TaC, release of boron from the gas supply port 22 can be suppressed. The gas supply port 22 is preferably a carbon member in which a plurality of SiC layers are laminated. The plurality of SiC layers are preferably epitaxial layers of SiC. Each of the plurality of SiC layers is preferably formed under the same conditions as those for forming the epitaxial layer 2. When a plurality of SiC layers are formed on the surface of the carbon member, release of boron from the member can be further suppressed.

The support 30 supports the SiC substrate 1. The support 30 is rotatable about an axis. The SiC substrate 1 is placed on the support 30, for example, in a state where the SiC substrate 1 is mounted on the susceptor 40. The susceptor 40 is conveyed into the chamber 20 with the SiC substrate 1 mounted thereon. The support 30 and the susceptor 40 may be made of the same material as, for example, the gas supply port 22. The lower heater 50 is provided, for example, in the support 30 and heats the SiC substrate 1. An upper heater 60 heats the upper part of the chamber 20.

The film-forming step is performed, for example, in a vertical furnace shown in FIG. 3. First, the SiC substrate 1 is conveyed to the film-forming space S. The SiC substrate 1 is conveyed, for example, in a state of being mounted on the susceptor 40. The temperature at which the SiC substrate 1 is transported into the film-forming apparatus 100 is preferably 500° C. or more. By keeping the transport temperature of the SiC substrate 1 high, the time required for the entire film-forming can be shortened.

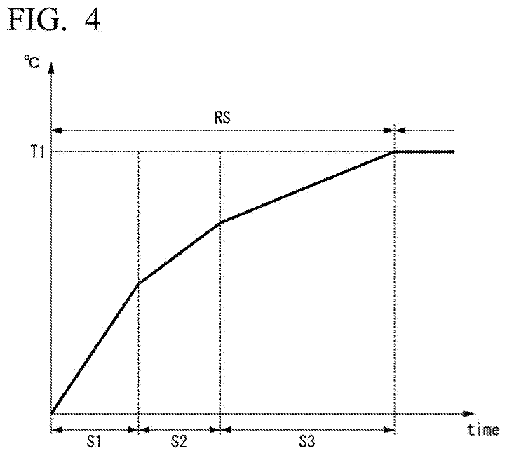

Next, an epitaxial layer 2 is formed on the transferred SiC substrate 1. FIG. 4 is an example of a manufacturing process of the SiC epitaxial wafer 10 according to the first embodiment. The film-forming step includes a temperature raising step RS for raising the temperature to the film-forming temperature T1. After the temperature raising step, the film-forming temperature T1 is maintained to form the epitaxial layer 2. The film-forming temperature T1 is, for example, 1500° C. or more.

The time required for the temperature raising step RS is, for example, 300 seconds or more and 750 seconds or less. When the time required for the temperature raising process RS is short, the strain of the SiC substrate 1 and the susceptor 40 increases, and the in-plane uniformity of the epitaxial layer 2 deteriorates. In addition, if the time required for the temperature raising process RS is short, the film-forming gas is rolled back due to convection caused by the temperature difference in the plane of the susceptor 40, and boron discharged from the susceptor 40 is taken into the wafer. When the time required for the temperature raising process RS is long, the amount of boron discharged from the member used in the film-forming apparatus 100 increases.

The temperature raising step RS includes, for example, a first temperature raising step S1, a second temperature raising step S2, and a third temperature raising step S3. The first temperature raising step S1, the second temperature raising step S2, and the third temperature raising step S3 have different temperature raising speeds. In the temperature raising step RS, the temperature raising speed may be changed twice or more, and further steps having different temperature raising speeds such as a fourth temperature raising step and a fifth temperature raising step may be included.

In the first temperature raising step S1, the temperature is raised at a first temperature raising speed. The first temperature rising speed is 100° C./min or more. The first temperature raising speed is faster than the second temperature raising speed in the second temperature raising step S2. In the first temperature raising step S1, the temperature is raised to, for example, about 1200° C.

The second temperature raising step S2 is performed after the first temperature raising step S1 and before the third temperature raising step S3. The second temperature raising step S2 is performed at a second temperature raising speed. The second temperature raising speed is slower than the first temperature raising speed and faster than the third temperature raising speed. The second temperature rising speed is, for example, 90% or less of the first temperature rising speed. In the second temperature raising step S2, the temperature is raised to, for example, about 1400° C.

The third temperature raising step S3 is performed after the second temperature raising step S2. The third temperature raising step S3 is performed at a third temperature raising speed. The third temperature raising speed is slower than the second temperature raising speed. The third temperature raising speed is, for example, 90% or less of the second temperature raising speed.

The time required for the entire temperature raising process RS can be shortened by increasing the first temperature raising speed. When the time required for the entire temperature raising process RS becomes shorter, the amount of boron released from the film-forming apparatus 100 is reduced. Further, by gradually slowing down the temperature raising speed, it is possible to suppress the strain of the SiC substrate 1 and the susceptor 40 from becoming too large.

After reaching the film-forming temperature T1, the epitaxial layer 2 is formed on the SiC substrate 1. At the time of film-forming, the temperature of the gas supply port 22 is set to 1200° C. or less, preferably 1100° C. or less. The temperature of the gas supply port 22 can be realized by adjusting the output of various heaters such as an upper heater and a lower heater. In addition, it may be realized by utilizing physical properties such as the structure and emissivity of members constituting the furnace. The temperature of the gas supply port 22 can be measured using, for example, a thermocouple. A simulation result by a computer may be used. The amount of boron released from the member increases as the temperature increases. The release amount of boron can be reduced by lowering the temperature of the gas supply port 22.

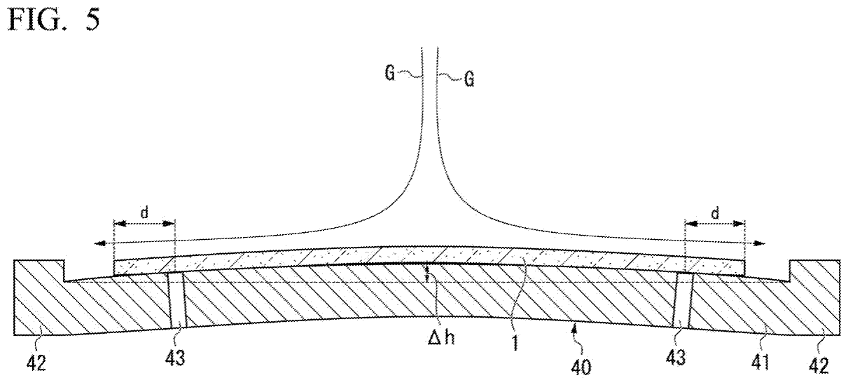

FIG. 5 is an enlarged view of the vicinity of the SiC substrate 1 in the film-forming apparatus for the SiC epitaxial wafer according to the first embodiment. The SiC substrate 1 is placed on a susceptor 40. The susceptor 40 has, for example, a support portion 41, an outer peripheral portion 42, and a through hole 43.

The SiC substrate 1 is mounted on the support portion 41. The outer peripheral portion 42 prevents the SiC substrate 1 from protruding to the outside during film formation. The outer peripheral portion 42 may be, for example, a separate ring-shaped member. The separate ring-shaped member is preferably a carbon member on which a plurality of SiC layers are laminated. The plurality of SiC layers are preferably epitaxial layers of SiC. Each of the plurality of SiC layers is preferably formed under the same conditions as those for forming the epitaxial layer 2. When a plurality of SiC layers are formed on the surface of the carbon member, boron release from the member can be further suppressed. The through hole 43 is a hole connecting the upper surface and the lower surface of the support portion 41.

The difference between the height position of the center of the mounting surface of the SiC substrate 1 and the height position of the outermost periphery is referred to as the height difference Δh. The height difference Δh can be measured by, for example, a laser displacement meter. First, a measurement port and a laser displacement meter are installed at the center and the outer periphery portion of the susceptor at the upper part of the furnace, and the warpage of the susceptor is measured by determining the difference in height between the center portion and the outer periphery portion at the film-forming temperature without installing a wafer. Then, a wafer is mounted on the susceptor, and the measurement is performed under the same conditions as when the warpage is measured without mounting the wafer, so that the height difference Δh can be measured. By forming the film while measuring the height difference Δh, an arbitrary height difference Δh can be maintained. Further, by selecting the wavelength of the laser light source, the warpage of the susceptor can be measured while the wafer is mounted. For example, in the case of a SiC wafer, when the wavelength of the laser light source is 600 nm or more, the laser passes through the SiC wafer, so that the warpage of the susceptor can be measured while the wafer is mounted. The height difference Δh at the time of film-forming is preferably 30 μm or more. That is, at the film-forming temperature T1, the height position of the center of the mounting surface of the SiC substrate 1 is preferably 30 μm or more higher than the height position of the outermost periphery. The height difference Δh at the film-forming temperature T1 is preferably 100 μm or less.

The range of the height difference Δh may be satisfied as long as it is satisfied at the film-forming temperature T1, and may not be satisfied at the ordinary temperature. When there is an outer peripheral portion 42, the boundary between the outer peripheral portion 42 and the mounting surface is the outer periphery of the mounting surface.

The height difference Δh can be controlled by, for example, a film-forming condition. The difference Δh tends to increase as the temperature raising speed is fast. In addition, the height difference Δh may be adjusted by the material constituting the susceptor 40. For example, the susceptor 40 may be made of two or more materials having different coefficients of thermal expansion, and the difference in height Δh may be adjusted using the difference in the coefficients of thermal expansion.

When the height difference Δh becomes large, the film-forming gas G flows from the center of the SiC substrate 1 to the outside in the vicinity of the upper surface of the SiC substrate 1, and it is possible to prevent the film-forming gas G from rolling back or the like. The roll back of the film forming gas G causes boron released from the member to be taken into the epitaxial layer 2 again. When the flow of the film-forming gas G from the center to the outside of the SiC substrate 1 is formed in the vicinity of the upper surface of the SiC substrate 1, the concentration of boron contained in the epitaxial layer 2 is lowered. If the height difference Δh is within a predetermined range, the difference in the film-forming conditions between the center and the outer peripheral portion of the epitaxial layer 2 is small, and the in-plane uniformity of the epitaxial layer 2 is enhanced.

At the time of film-forming, gas may be supplied to the back surface of the SiC substrate 1 through the through hole 43. The gas supplied to the back surface side of the SiC substrate 1 prevents the film-forming gas G from flowing into the back surface of the SiC substrate 1. The gas supplied to the back surface is a purge gas that is inert to SiC.

The purge gas is preferably supplied toward the back surface of the SiC substrate 1 from a position 20 mm or more inside the outermost periphery of the SiC substrate 1. For example, the distance d between the through hole 43 and the outermost periphery is preferably 20 mm or more. When the supply position of the purge gas to the back surface of the SiC substrate 1 satisfies the above condition, the flow of the film-forming gas G can be suppressed from being disturbed by the purge gas from the back surface.

In the film-forming method of the SiC epitaxial wafer 10 according to the present embodiment, the flow of the film-forming gas G can be controlled by using a vertical furnace and defining a temperature raising step, thereby preventing the unreacted gas from being rolled back to the epitaxial layer 2. Further, in the film-forming method of the SiC epitaxial wafer 10 according to the present embodiment, by setting the temperature of the gas supply port 22, the amount of boron released from the member itself can be reduced. As a result, in the film-forming method of the SiC epitaxial wafer 10 according to the embodiment, the concentration of boron in the center of the epitaxial layer 2 can be set to less than 5.0×10¹² cm⁻³. The concentration of boron on the outer periphery of the epitaxial layer 2 can be 1.0×10¹⁴ cm⁻³ or less.

Since boron is a lifetime killer, the concentration of boron must be less than 5.0×10¹² cm⁻³ in order to obtain a sufficient conductivity modulation effect in a bipolar device. Since the concentration of boron in the center of the epitaxial layer 2 of the SiC epitaxial wafer 10 according to the present embodiment is less than 5.0×10¹² cm⁻³, a sufficient conductivity modulation effect can be obtained in the bipolar device. That is, by using the SiC epitaxial wafer 10 according to the present embodiment, a high-quality device can be manufactured.

The lower the impurity concentration determining the conductivity type in the epitaxial layer 2, the greater the influence of the boron concentration on the carrier concentration uniformity. The lower the concentration of nitrogen in the epitaxial layer 2, the higher the ratio of boron to nitrogen contained in the epitaxial layer 2. In other words, in the epitaxial layer 2 having a low impurity concentration for determining the conductivity type, it is valuable to have a low boron concentration.

Although preferred embodiments of the present disclosure have been described in detail above, the present disclosure is not limited to specific embodiments, and various modifications and modifications can be made within the scope of the subject matter of the present disclosure described in the claims.

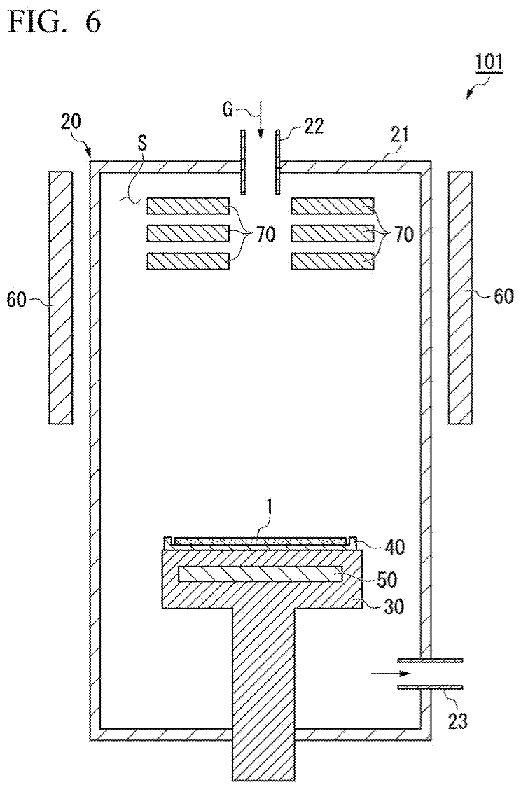

For example, FIG. 6 is a schematic view of another example of a film-forming apparatus for producing a SiC epitaxial wafer according to the first embodiment. The film-forming apparatus 101 shown in FIG. 6 differs from the film-forming apparatus 100 of FIG. 3 in that an upstream member 70 is located in the middle of the gas flow path from the gas supply port 22 in the film-forming space S to the mounting surface of the SiC substrate 1. In the description of the film-forming apparatus 101, the same components as those of the film-forming apparatus 100 are denoted by the same reference numerals. When the film-forming apparatus 101 is used, the epitaxial layer 2 is formed by the same method as the film-forming apparatus 100.

The upstream member 70 is a member located in the film-forming space S and located between the gas supply port 22 and the mounting surface of the SiC substrate 1 in the gas flow direction. The upstream member 70 is, for example, a reflector for reflecting radiation from a heater, a tapered member for controlling gas flow, and the like.

The upstream member 70 includes, for example, a carbon member and a SiC or TaC layer coating its surface. Since the surface is coated with SiC or TaC, release of boron from the upstream member 70 can be suppressed.

In this modified example, the flow of the film-forming gas G can be controlled by using a vertical furnace and defining a temperature raising step, thereby preventing the unreacted gas from being rolled back to the epitaxial layer 2. By setting the temperatures of the gas supply port 22 and the upstream member 70 in the middle of the gas flow path in the film-forming space S, the discharge amount of boron from the member itself can be reduced. As a result, even in the modified example, the concentration of boron at the center of the epitaxial layer 2 can be set to less than 5.0×10¹² cm⁻³. The concentration of boron on the outer periphery of the epitaxial layer 2 can be 1.0×10¹⁴ cm⁻³ or less.

### EXAMPLES

### Example 1

SiC substrates of 150 mm in diameter were prepared. The epitaxial layer 2 was formed on the SiC substrate 1 using a vertical furnace similar to the film-forming apparatus 100 shown in FIG. 3. A separate ring-shaped member coated by a plurality of SiC layers thereon was used for the outer peripheral portion 42. The temperature raising step was divided into three steps, and the temperature raising speed was changed twice. The first temperature raising speed was 100° C./min or more. The second temperature raising speed was set to be less than 80% of the first temperature raising speed. The third temperature raising speed was set to be less than 80% of the second temperature raising speed. The film-forming temperature was 1600° C. or higher and less than 1700° C. The time required for temperature rise was 300 seconds or more and less than 750 seconds.

When the epitaxial layer 2 was formed, purge gas was supplied from the back surface side of the SiC substrate 1. The purge gas was supplied so as to hit a position 20 mm or more inside the outer periphery of the SiC substrate 1. In the temperature range of 1600° C. or higher and less than 1700° C., the height position of the center of the mounting surface of the SiC substrate 1 was set to be 30 μm or more higher than the height position of the outermost periphery. The temperature of the gas supply port 22 at the time of film-forming was 1100° C. or less.

After production, the concentration of boron at the center pl of the SiC epitaxial wafer 10 was measured. The concentration of boron at the center p1 of Example 1 was 2.0×10¹² cm⁻³.

### Comparative Example 1

SiC substrates of 150 mm in diameter were prepared. In Comparative Example 1, a horizontal furnace having a gas supply port on the side of the SiC substrate was used. As a part of the member constituting the furnace, a carbon member not covered with the SiC epitaxial layer was used. Then, an epitaxial layer 2 was formed on the SiC substrate 1 using a horizontal furnace. The temperature raising process was one step, and the temperature raising speed was not changed. The temperature raising speed was set to 100° C./min or less. The film-forming temperature was 1600° C. or higher and less than 1700° C. The time required for temperature rise was more than 750 seconds.

In the comparative example, no purge gas was supplied to the back surface side of the SiC substrate 1. Since the temperature raising speed is slower than that of the Example, the height position of the center of the mounting surface of the SiC substrate 1 was less than 30 μm from the height position of the outermost periphery in a temperature range of 1600° C. or higher and less than 1700° C.

After production, the concentration of boron at the center p1 of the SiC epitaxial wafer of Comparative Example 1 was measured. The boron concentration in the center p1 of Comparative Example 1 was 1.7×10¹⁴ cm⁻³.

What is claimed is:

1. A SiC epitaxial wafer, comprising:
a SiC substrate; and,
an epitaxial layer of SiC laminated on the SiC substrate,
wherein the epitaxial layer contains an impurity element which determines the conductivity type of the epitaxial layer and boron which has a conductivity type different from the conductivity type of the impurity element, and
the concentration of boron in the center of the epitaxial layer is less than 5.0×10¹² cm⁻³.

2. The SiC epitaxial wafer according to claim 1, wherein the diameter is 150 mm or more.

3. The SiC epitaxial wafer according to claim 1, wherein the diameter is 200 mm or more.

4. A method of manufacturing a SiC epitaxial wafer, comprising:
a film-forming step of forming an epitaxial layer of SiC on a SiC substrate using a vertical furnace having a gas supply port above a mounting surface of the SiC substrate,
wherein the film-forming step comprises a temperature raising step of raising the temperature to a film-forming temperature while changing the temperature raising speed in the order of a first temperature raising speed, a second temperature raising speed, and a third temperature raising speed,
wherein the first temperature raising speed is faster than the second temperature raising speed, the second temperature raising speed is faster than the third temperature raising speed, and the first temperature raising speed is 100° C./min or more, and
wherein in the film forming step, the temperature of the gas supply port and an upstream member in the middle of the gas flow path from the gas supply port to the mounting surface is set to 1200° C. or less.

5. A method of manufacturing a SiC epitaxial wafer according to claim 4,
wherein the gas supply port and the upstream member are carbon members in which a plurality of SiC layers are laminated.

6. A method of manufacturing a SiC epitaxial wafer according to claim 4,
wherein in the mounting surface of the SiC substrate, the height position of the center is 30 μm or more higher than the height position of the outer periphery at the film-forming temperature.

7. A method of manufacturing a SiC epitaxial wafer according to claim 4,
wherein the time required for the temperature raising step is 300 seconds or more and 750 seconds or less.

8. A method of manufacturing a SiC epitaxial wafer according to claim 4,
wherein the SiC substrate is transferred to the vertical furnace at a temperature of 500° C. or higher.

9. A method of manufacturing a SiC epitaxial wafer according to claim 4,
wherein in the film-forming step, a purge gas is supplied from the back surface of the SiC substrate, and the purge gas is supplied from a position 20 mm or more inside the outer periphery of the SiC substrate.
